(19) United States
(12) Patent Application Publication
(10) Pub. No.: US 2015/0226497 A1
(43) Pub. Date: Aug. 13, 2015

(54) Thermal Devices For Controlling Heat Transfer

(71) Applicant: The Regents of the University of California, Oakland, CA (US)

(72) Inventor: Yun Wang, Irvine, CA (US)

(21) Appl. No.: 14/619,781

(22) Filed: Feb. 11, 2015

Related U.S. Application Data
(60) Provisional application No. 61/938,268, filed on Feb. 11, 2014.

(51) Int. Cl. F28F 3/12; H05K 7/20; A41D 13/005

(52) U.S. Cl. CPC F28F 3/12; A41D 13/0053; H05K 7/20263

(57) ABSTRACT

In one embodiment, a thermal device includes a sealed housing that defines an interior space, a liquid-attracting element provided on one side of the interior space, a liquid-repelling element provided on another side of the interior space opposite to the liquid-attracting element, and a liquid provided within the interior space.

### CROSS-REFERENCE TO RELATED APPLICATION

This application claims priority to co-pending U.S. Provisional Application Ser. No. 61/938,268, filed Feb. 11, 2014, which is hereby incorporated by reference herein in its entirety.

### BACKGROUND

There are various applications in which it would be desirable to control the direction of heat transfer. For example, in some situations it may be desirable to enable heat from within clothing or equipment to escape to the outside environment without enabling heat from the environment to enter. In other situations, it may be desirable to direct heat from the environment to the wearer's body to help him or her maintain body temperature. While such heat transfer control would be useful in various applications, there are few devices that enable it.

### BRIEF DESCRIPTION OF THE DRAWINGS

The present disclosure may be better understood with reference to the following figures. Matching reference numerals designate corresponding parts throughout the figures, which are not necessarily drawn to scale.

FIG. 1 is a perspective view of an embodiment of a thermal device.

FIG. 2 is a side cross-sectional view of a first internal configuration for the thermal device of FIG. 1.

FIG. 3 is a side cross-sectional view of a second internal configuration for the thermal device of FIG. 1.

FIG. 4A is a graph that plots capillary pressure curves for two porous media.

FIG. 4B includes schematic diagrams that illustrate initial and final equilibrium reduced water saturation.

FIGS. 5A and 5B are side views of test apparatus that was used to evaluate a prototype thermal device in two different orientations.

FIG. 6 is a graph that plots temperature versus time to illustrate the performance of the prototype thermal device in two different orientations.

FIG. 7 is a front view of an embodiment of a wearable garment that includes thermal devices.

FIG. 8 is a side view of an embodiment of a wearable helmet that includes thermal devices.

FIG. 9 is a schematic view of an electrical device that incorporates a thermal device to enable heat dissipation from inside and thermal protection from outside.

FIG. 10 is a schematic view of a thermal storage unit that incorporates a thermal device.

### DETAILED DESCRIPTION

As described above, it would be desirable to control heat transfer. Disclosed herein are thermal devices for controlling such heat transfer. In some embodiments, the thermal devices act as “thermal diodes” that can be used to control the direction of heat transfer. More particularly, such thermal devices can be used to enable heat transfer flow in a first direction but inhibit heat transfer flow in a second direction opposite to the first direction. In some embodiments, the thermal devices are temperature sensitive. More particularly, the thermal conductivity of the devices increases with increasing ambient temperatures. As described below, the thermal devices can comprise a liquid-attracting element and a liquid-repelling element that are both enclosed within a sealed housing along with a liquid. When the elements are provided on opposite sides of the interior space of the housing, heat can flow from the hydrophilic side to the hydrophobic side of the device. Such thermal devices can be incorporated into various other objects, such as clothing, helmets, gloves, electrical devices, thermal energy harvester/storage units, vehicles, buildings, and the like.

In the following disclosure, various specific embodiments are described. It is to be understood that those embodiments are example implementations of the disclosed inventions and that alternative embodiments are possible. All such embodiments are intended to fall within the scope of this disclosure.

Disclosed below are thermal devices having unique thermal properties including, for example, “thermal diodicity” and temperature sensitive thermal conductance. These unique properties offer great benefits, particularly when the devices are integrated to wearable clothing or equipment. In terms of thermal diodicity, a worn garment or piece of equipment incorporating the thermal devices can provide the dual functions of thermal conducting (e.g., in summer) and thermal insulating (e.g., in winter). Regarding the temperature sensitive thermal conductance, as the ambient temperature increases, the thermal resistance of the thermal devices decreases. Accordingly, the thermal devices are more efficient at enabling heat dissipation from a worn garment or piece of equipment in higher ambient temperatures. In colder ambient temperatures, the thermal resistance of the thermal devices is increased, in which case the garment or equipment is more resistive to body heat loss.

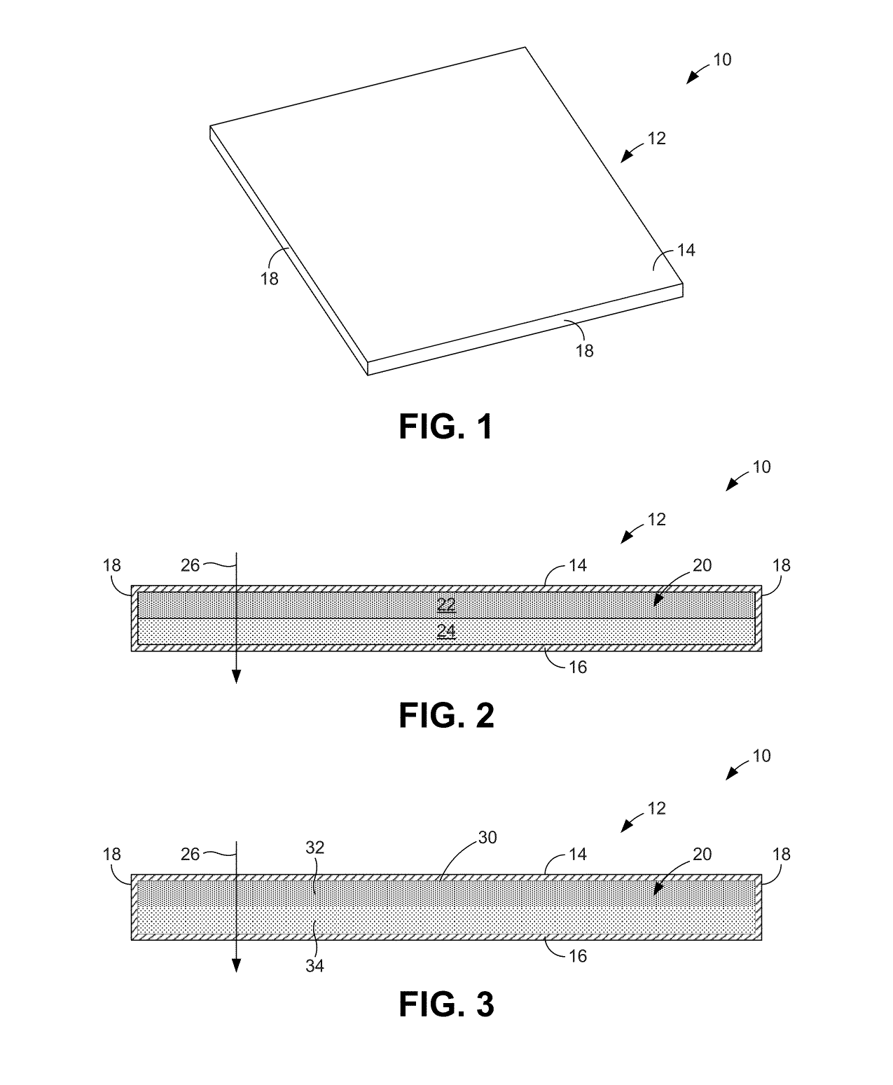

FIG. 1 illustrates an embodiment of a thermal device 10. As shown in the figure, the device 10 comprises a sealed outer housing 12 that defines a thin-film structure well suited for incorporation into other objects. The housing 12 includes a first or top plate 14, a second or bottom plate 16 (see FIGS. 2 and 3), and multiple side walls 18 that connect the top and bottom plates. In the illustrated embodiment, the top and bottom plates 14, 16 are planar and rectangular (e.g., square). It will be appreciated, however, that other shapes are possible. Irrespective of their shapes, the top and bottom plates 14, 16 are made of a thermally conductive material. In some embodiments the conductive material is a corrosion-resistant metal such as stainless steel, copper, or titanium, or a non-corrosion-resistant metal that is coated with a corrosion-resistant material. In other embodiments, the conductive material is a non-metal material such as carbon or a conductive polymer. Together, the plates 14, 16 and side walls 18 form a sealed enclosure that can contain elements described below. In some embodiments, the housing 12 has a width dimension of approximately 5 to 100 mm, a length dimension of approximately 5 to 100 mm, and a height (thickness) dimension of approximately 0.1 to 10 mm. In some embodiments, the plates 14, 16 and the side walls 18 can each be approximately 0.05 to 1 mm thick.

In some embodiments, the housing 12 can be formed using a stamping process. Stamping is a mature machining technique that can be used to shape or cut metal by deforming it with a die. It is a quick, cost effective fabrication method and can be readily extended for mass production. Assuming a metal sheet that is approximately 0.3 to 0.5 mm thick, multiple sheets can be stamped at the same time, yielding further reduced fabrication costs and increased production rates. Hot-press stamping ensures quick, uniform compression and rapid sealing of the device 10.

FIG. 2 illustrates a first example internal configuration for the thermal device 10 of FIG. 1. As shown in FIG. 2, the outer housing 10 defines a sealed internal space 20. In some embodiments, the space 20 is maintained at a vacuum of approximately 1 to 10⁵ Pa. Provided within the space 20 in the embodiment of FIG. 2 is a porous liquid-attracting element 22 and a porous liquid-repelling element 24, which are positioned at opposite ends of the space 20. In the illustrated embodiment, the liquid-attracting element 22 is positioned next to the top plate 14 and the liquid-repelling element 24 is positioned next to the bottom plate 16. As their names suggest, the liquid-attracting element 22 has liquid-attracting properties and the liquid-repelling element 24 has liquid-repelling properties. In cases in which the liquid at issue is water or a water-based liquid, the liquid-attracting element 22 is a hydrophilic element and the liquid-repelling element 24 is a hydrophobic element.

The liquid-attracting and liquid-repelling elements 22, 24 can be made of substantially any porous materials that either inherently have the respective liquid-attracting or liquid-repelling properties or that are treated or coated to have those properties. In some embodiments, the liquid-attracting element 22 comprises charge-polarized molecules that are capable of hydrogen bonding, enabling them to dissolve more readily in water. In some embodiments, the liquid-repelling element 24 comprises one or more of an alkane, oil, fat, grease, polytetrafluoroethylene (PTFE), or chemicals or materials having the lotus effect. The liquid attracting or repelling properties can also be affected by the porosity and permeability of the elements 22, 24. Accordingly, the porosity and permeability of the elements 22, 24 can be controlled in a manner that enhances liquid attracting and repelling, respectively. In some embodiments, each element 22, 24 is approximately 0.05 to 5 mm thick.

In some embodiments, the elements 22, 24 can be fabricated using a papermaking process that utilizes fibers (e.g. synthetic fibers). In other embodiments, the elements 22, 24 can be fabricated by drying ink or paste using particle-solvent mixtures. In papermaking, chopped fibers are dispersed in water with binders, such as polyvinyl alcohol, to produce paper rolls through sieves. After drying at temperature and with compression, the fibers will be tied together by the binders, forming thin porous layer. By controlling the number of sieving, the thickness of the layers can be altered. By adjusting the fiber diameter, one can modify the pore dimension, which determines permeability. In this process, the fibers can be primarily aligned in the transverse direction, and the resulting porous layer can be seen as a stack of several thin sections consisting of laterally orientated fibers. In general, this porous layer has a high porosity (e.g., up to 90%) and a large tortuosity in its solid fiber network (e.g., >10). Thus, its structure provides a highly torturous, solid structure that depresses thermal conductivity and a high porosity that promotes effective heat pipe effect.

For the drying ink/paste method, small particles can be mixed with solvents, along with a binder and PTFE solution. By spraying or printing on the surface of another porous layer, followed by drying under proper thermal condition, a new thin porous layer is obtained that is made of packed fine particles. The thickness can be controlled by a spaying or printing process, and the pore size is determined by the particle dimension. This method, however, generates a porous layer of relatively low porosity and solid-structure tortuosity. Its advantage is that one can control the surface property by adjusting PTFE loading so as to avoid any extra surface treatment.

The porous layer's surface wettability plays the critical role of controlling liquid flow and promoting the desirable heat pipe effect, thus it must be carefully designed and fabricated. Surface wettability can be modified through a few standard methods such as adding PTFE content, growing nano-structures over the solid matrix structure, and adding other chemical agents through self-assembled monolayer (SAM) method.

Adding PTFE loading is widely adopted due to its cost efficiency and easy scale up for mass production with durable yielded surface property. In this method, the porous medium can be dipped into aqueous PTFE suspensions. The wet layers can then be placed in an oven for drying to remove any residual solvent. A temperature above 300° C. will sinter PTFE and fix it to the solid structure surface, and the PTFE binding with many substrates is strong and resists erosion. Because PTFE is a hydrophobic agent, adding it will increase medium's hydrophobicity. In order to achieve the targeted hydrophobicity (i.e. contact angle), one can carefully control the PTFE loading. In general, larger PTFE loading yields more hydrophobic surface or larger contact angle.

Studies have been proposed to grow nano-structures such as nanotubes on the solid surface to modify surface wettability. Nano-structures can be created through gas-phase techniques, such as chemical vapor deposition (CVD), where nanotubes are formed by the decomposition of a carbon-containing gas. This gas-phase technique is amenable to continuous processes since the carbon source is continually replaced by flowing gas. By controlling the amount of nano-structure (or the deposition time), the surface roughness and wettability can be altered.

Self-assembled monolayer (SAM) coating is a popular method to modify surface property. It coats a special chemical agent on the substrate surface. The head groups bind closely to the surface, while the hydrophobic miscelles stretch far away from the surface. By varying the amount of chemical agents on a substrate, one can alter wettability. By removing the monolayers (e.g. using ultraviolet sources), the added hydrophobicity can be eliminated.

With continued reference to FIG. 2, also provided within the interior space 20 is a liquid that has a volume that is less than the total volume of the interior space of the housing 12. In some embodiments, the liquid comprises water or a water-based liquid. In other embodiments, the liquid can comprise another liquid, such as a refrigerant or other high-temperature liquid. Because of the nature of the liquid-attracting and liquid-repelling elements 22, 24, the liquid naturally migrates away from the liquid-repelling element and toward the liquid-attracting element, thereby creating a two-phase system in which a liquid phase is contained in the liquid-attracting element and a vapor phase is contained in the liquid-repelling element. This two-phase system enables a heat transfer flow in similar manner to that provided by a heat pipe. Accordingly, heat will flow in one direction, i.e., from the liquid-attracting side of the thermal device 10 to the liquid-repelling side of the device, as indicated by arrow 26. Accordingly, heat flow can be controlled simply through selection of the orientation of the thermal device 10 and, more particularly, the locations of the liquid-repelling and liquid-attracting elements 22, 24.

FIG. 3 illustrates a second example internal configuration for the thermal device 10 of FIG. 1. The configuration shown in FIG. 3 is the same as that shown in FIG. 2 with the exception of the independent liquid-attracting and liquid-repelling elements 22, 24 are replaced with a single element 30 that has a liquid-attracting side 32 and a liquid-repelling side 34. In such a case, the element 30 can be a porous element, such as one of those described above, that has been treated on one or both sides to have the desired liquid-attracting or liquid-repelling properties. It is noted that the liquid-attracting side 32 and liquid-repelling side 34 can also be referred to as liquid-attracting and liquid-repelling “elements” even though they are portions of the same component.

As described above, the thermal diodicity of the thermal device 10 is promoted by the heat pipe effect. In the heat pipe effect, the heat flow direction must be the same as the vapor diffusion and opposite to the capillary liquid flow. It is noted that both vapor diffusion and liquid flow are necessary for heat pipe effect to occur. Thus, by controlling either vapor diffusion or liquid flow, the heat pipe effect can be promoted or depressed. For vapor diffusion, it is difficult to enable diffusive transport in only one direction, given that the random walk (i.e. no direction preference) determines the diffusive nature. For liquid flow, external forces can be applied to manipulate liquid flow. As an example, gravitational force tends to drive liquid downward and impose drag on upward flow. In porous media, an important force for flow is capillary action, arising from surface tension σ. Surface tension presents at the interface between phases, e.g. the vapor and liquid phases, which yields a pressure difference across the phase interface:

$${P}_{c} = {P}_{g} - {P}_{l} = ( \frac{1}{{r}_{1}} + \frac{1}{{r}_{2}} ) σ \qquad [ Equation 1 ]$$

where subscripts c, g, and l denote capillary, gas, and liquid, respectively, and r₁ and r₂ measure the curvature of the interface in any two perpendicular planes. The above is the well-known Laplace or the Young-Laplace equation. In porous media, the interfacial morphology is affected by the pore dimension and surface wettability (measured by contact angle θ_{c}), thus the capillary force is determined by these parameters, as empirically given by:

$${P}_{g} - {P}_{l} = {P}_{c} = σ cos ( {θ}_{c} ) {( \frac{ɛ}{K} )}^{1 / 2} J ( s ) \qquad [ Equation 2 ]$$

The Leverett J function J(s) is determined by the material wettability:

$$J ( s ) = \{ \begin{matrix}1.417 ( 1 - s ) - 2.120 {( 1 - s )}^{2} + 1.263 {( 1 - s )}^{3} & for {θ}_{c} < {90}^{∘} \\ 1.417 s - 2.120 {s}^{2} + 1.263 {s}^{3} & for {θ}_{c} > {90}^{∘}\end{matrix} \qquad [ Equation 3 ]$$

where ε denotes porosity and K the permeability. The variable s represents saturation and is defined as the volume fraction of liquid in the pore. Because cos(θ)>0 under θ_{c}<90° and cos(θ)<0 under θ_{c}>90°, Pₗ in a hydrophobic medium (θ_{c}>90°) is always larger than a hydrophilic one (θ_{c}<90°) if other medium parameters are the same. This is significant given that a gradient in Pₗ tends to drive liquid flow from a higher Pₗ region to a lower one. Thus, by manipulating the surface wettability gradient, one can control liquid flow direction.

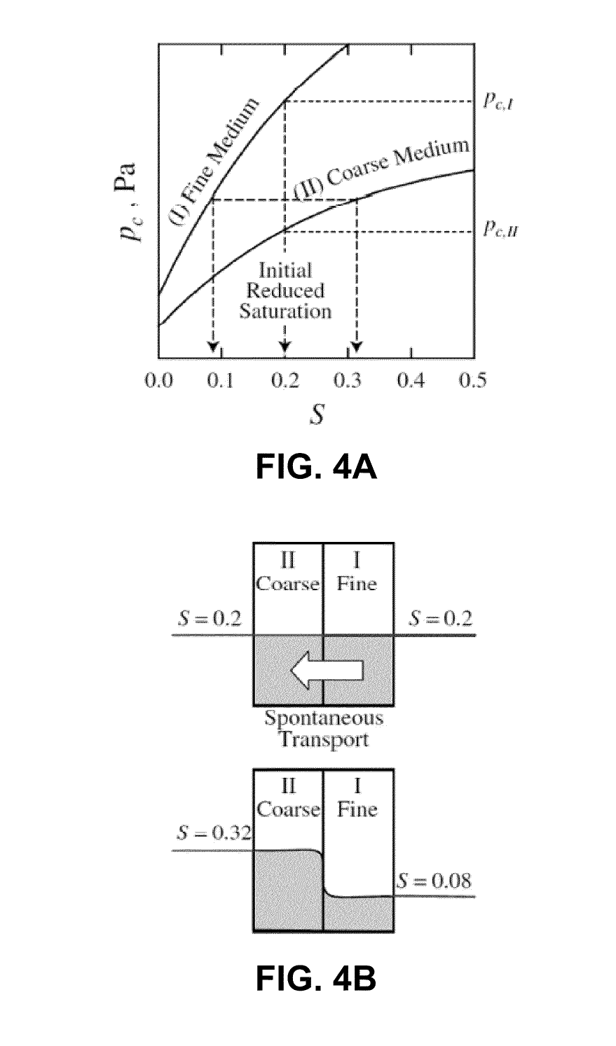

Other control parameters on Pₗ are porosity and permeability, as shown in Eq. 2. FIG. 4A sketches the P_{c} profiles (hence Pₗ because P_{g} is constant throughout the medium in this case) in two distinct media: one being a fine medium that has a small mean pore dimension and hence low permeability, the other being a coarse medium. The fine medium has a higher capillary pressure than the coarse medium under the same conditions, yielding a liquid flow from the fine medium towards the coarse one, and yielding a higher content of liquid water in the latter, as shown in FIG. 4B

Turning to the physics related to the liquid driving force arising from material heterogeneity, a generalized expression of the water flux driven by material heterogeneity can be derived as follows:

$$\frac{{λ}_{l} {λ}_{g}}{V} K ▽ {P}_{c} ( σ , {θ}_{c} , ɛ , K , s ) = \frac{{λ}_{l} {λ}_{g}}{V} K ( \frac{\partial {P}_{c}}{\partial σ} ▽ σ + \frac{\partial Pc}{\partial θ c} ▽ {θ}_{c} + \frac{\partial {P}_{c}}{\partial ɛ} ▽ ɛ + \frac{\partial {P}_{c}}{\partial K} ▽ K + \frac{\partial {P}_{c}}{\partial s} ▽ s ) \qquad [ Equation 4 ]$$

where the left side of the equation represents water flux and A denotes the mobility of individual phase. By designing and fabricating material heterogeneity (e.g. wettability or the contact angle θ_{c}), one can control liquid flow and its flux. By allowing the liquid flow only in one direction, one can create a heat pipe effect occurs in one direction only, i.e. opposite to the liquid flow path. Given that the heat pipe effect is a heat conductance added to the intrinsic medium's conductivity, the overall conductance in the two opposite directions will be different, yielding thermal diodicity. The degree of the thermal diodicity can be adjusted through the heat-pipe apparent conductance and the medium's intrinsic conductivity.

In some embodiments, the thermal device can have a target diodicity of at least approximately 20, i.e. the ratio of the thermal conductivities in the two opposite directions is at least approximately 20. Specially, the targeted thermal resistance can be less than 0.003 m² F/W in the conductive direction and greater than 0.06 m² F/W in the opposite direction. Assuming the device to be less than 2 mm thick, this would yield thermal conductivity of greater than 0.71 and less than 0.036 W/m F, respectively. In comparison, ambient air has a conductivity of 0.024 W/m F.

As noted above, the interior space of the thermal device can be maintained under a vacuum. The porous medium's thermal conductivity k^{eff} can be generalized by:

k^{eff}=εₛⁿ^{ₛₖ}ₛ+eₗⁿ^{ₗ}kₗ+ε_{g}ⁿ^{_{g}}k_{g} [Equation 5]

where E and n denote the volume fraction and tortuosity, respectively, and s, l, and g represent the solid, liquid, and gas phases that are present inside the medium.

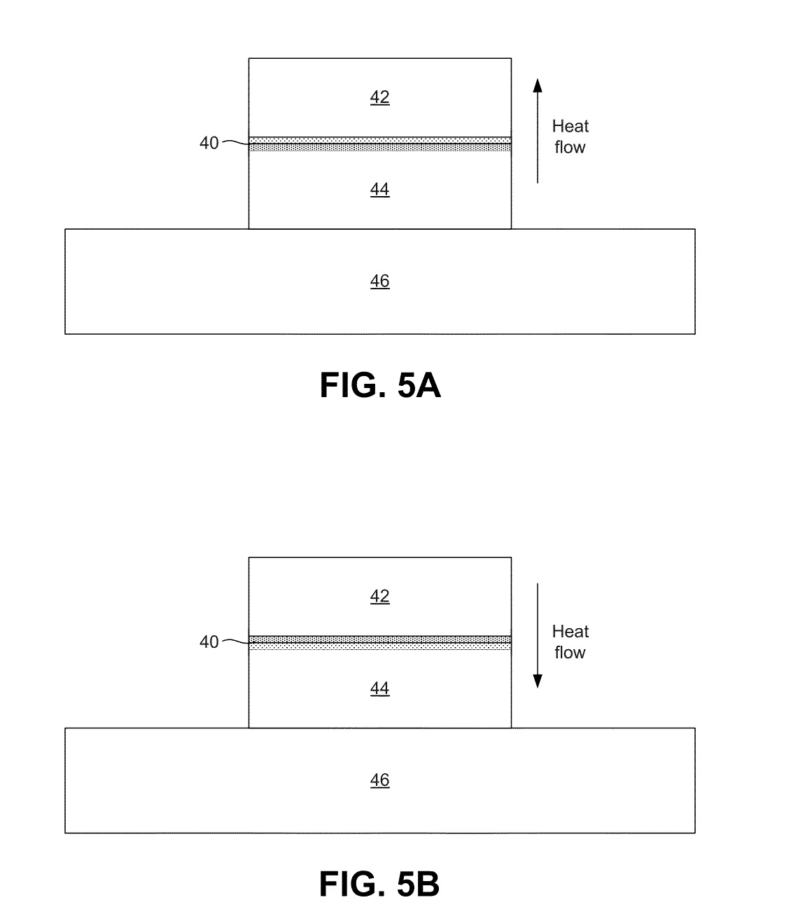

A thermal device having thermal diodicity was fabricated for evaluation. FIGS. 5A and 5B show the thermal device 40 positioned between a top block 42 and a bottom block 44 of aluminum while the device is in different orientations. The thermal device 40 had a construction similar to that illustrated above in relation to FIGS. 1 and 2. More particularly, the thermal device 40 included a hydrophilic element (carbon cloth) and a hydrophobic element (nylon sheet) that were contained along with a volume of water within a stainless steel housing. The housing was approximately 1 mm thick and 2 cm in diameter and had a volume of approximately 0.4 cm³. The volume of water in the housing was less than the total void space of the carbon paper.

As shown in FIGS. 5A and 5B, the bottom block 44 was positioned on a heat source 46 that was set at a constant temperature to evaluate heat transfer through the thermal device 40. During the testing, the thermal device 40 was placed between the blocks 42, 44 in a “forward” orientation in which the hydrophilic element was the bottom element and the hydrophobic element was top element (in which case heat should flow well through the device from the bottom block 44 to the top block 42) and in a “backward” orientation in which the hydrophobic element was the bottom element and the hydrophilic element was top element (in which case heat should now flow well through the diode from the bottom block 44 to the top block 42). During the testing, the heat source 46 was maintained at 105° C.

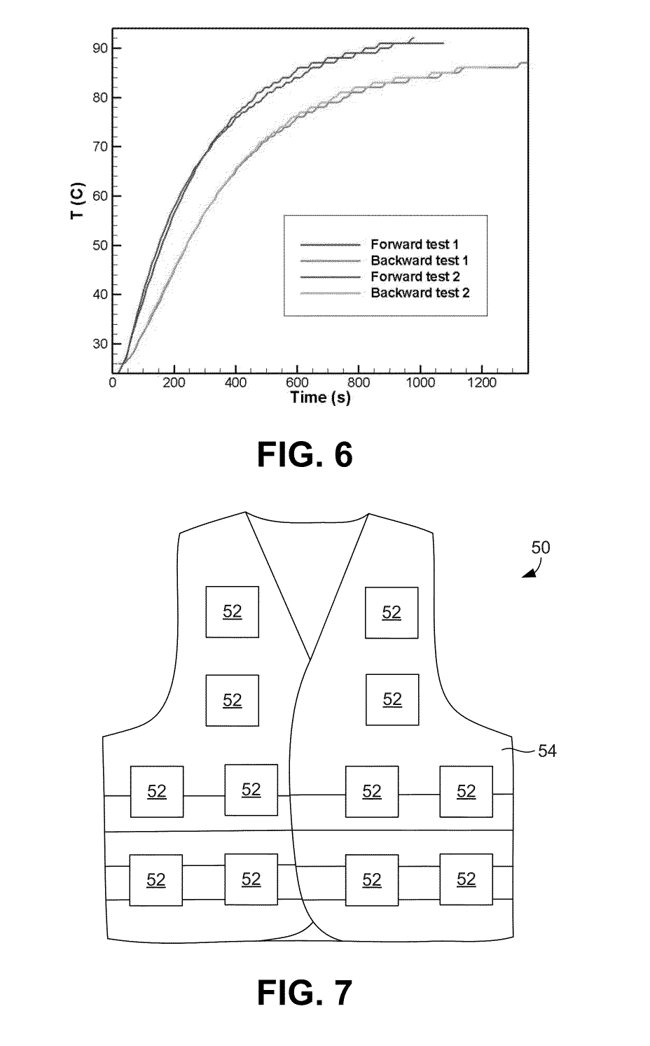

The results of the testing are shown in FIG. 6. As indicated in this figure, there was a 2× to 3× difference in the thermal conductivity of the thermal device 50 depending upon the orientation of the diode. The difference would likely have been much greater if a deeper vacuum in the housing had been attained.

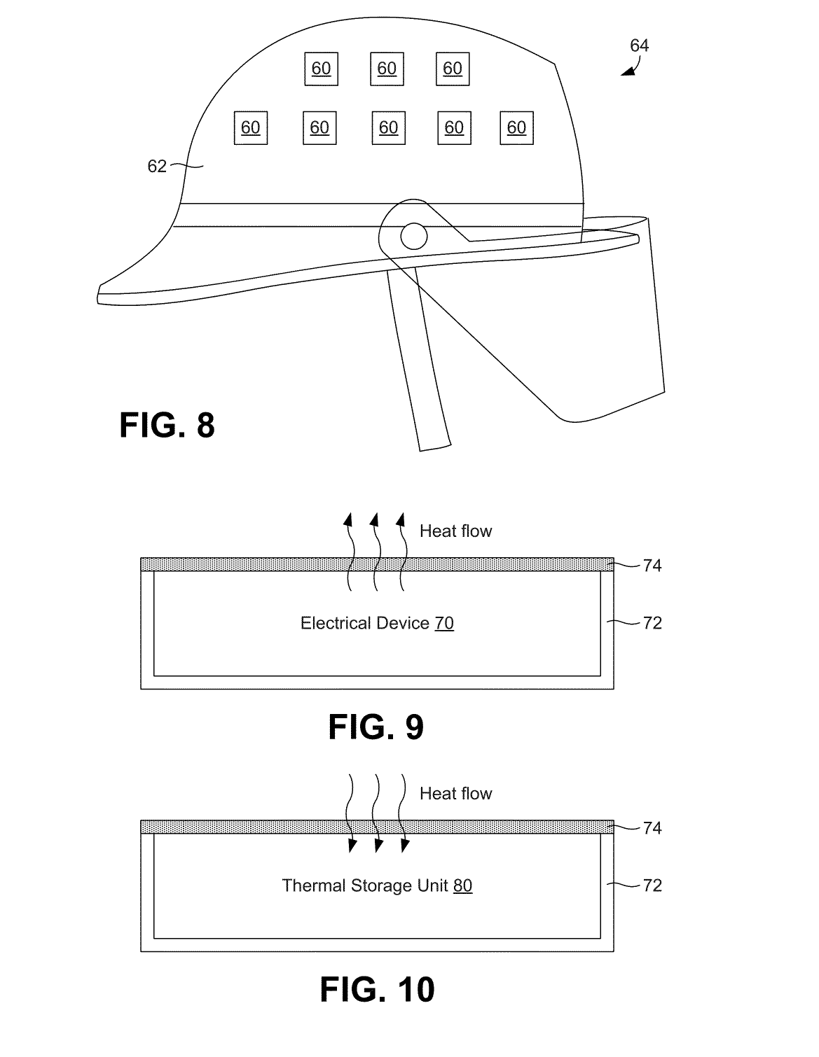

There are many applications for a thermal devices such as those described above. For example, small thermal devices (e.g., 1-4 in. in diameter or length) can be incorporated into garments or wearable equipment to aid removing heat when the user is in hot environments or to aid in maintaining body heat when the user is in cold environments. FIGS. 7 and 8 illustrate an example application of the thermal devices to a garment and a piece of equipment, respectively. Beginning with FIG. 7, illustrated is a high-visibility vest 50 that is equipped with multiple thermal devices 52 each having a construction similar to that described above. As shown in FIG. 7, the thermal devices 52 are integrated into a substrate (e.g., outer layer) 54 of the vest at various locations so that heat can be dissipated or absorbed at various points on the wearer's body. In some embodiments, the vest 50 can be reversible. In such a case, the vest 50 can be worn in a first orientation in which the thermal devices 52 are configured to take heat away from the user (e.g., in summer), and can be worn in a second (reverse) orientation in which the thermal devices are configured to transfer heat to the user (e.g., in winter). In the latter case, this heat could be, for example, heat generated by incident sunlight or another heat source.

Referring next to FIG. 8, thermal devices 60 are integrated into a substrate (e.g., outer shell) 62 of a helmet 64 to either remove heat from or provide heat to the user's head. In some embodiments, the thermal devices 60 can be reversible to facilitate both functions.

As noted above, the thermal devices' thermal conductivity can, in some embodiments, be temperature sensitive. In some embodiments, the devices' thermal conductivity has the potential of increasing by over 20% for every increase of ambient temperature of approximately 4° F. In such a case, the thermal devices' ability to dissipate body heat significantly increases in hotter environments.

It is noted that the thermal devices do not need to be used in conjunction with a wearable article. For example, similar thermal devices, perhaps with greater width and length dimensions, can be incorporated into a roof of a vehicle to remove or retain heat. In a similar manner, thermal devices can be incorporated into the roof, windows, or shades of buildings to remove heat from or supply heat to the building. In addition, the thermal devices can be used to dissipate heat from a heat-producing electrical device. FIG. 9 schematically illustrates an example of this. In this figure, an electrical device 70 has an outer housing 72 that is formed as or comprises a thermal device 74 configured as described above. As shown in the figure, heat flows away from the electrical device 70 because of the thermal device 74. FIG. 10 shows a further application. In this case, a thermal storage unit 80 has an outer housing 82 that is formed as or comprises a thermal device 84 configured as described above. As shown in the figure, heat flows into the thermal storage unit 80 because of the thermal device 84.

1. A thermal device comprising:
a sealed housing that defines an interior space;
a liquid-attracting element provided on one side of the interior space;
a liquid-repelling element provided on another side of the interior space opposite to the liquid-attracting element; and
a liquid provided within the interior space.

2. The thermal device of claim 1, wherein the housing is made of a material having high thermal conductivity.

3. The thermal device of claim 1, wherein the housing is made of a metal material.

4. The thermal device of claim 1, wherein at least one of the liquid-attracting element and the liquid-repelling element is made of a porous material.

5. The thermal device of claim 1, wherein at least one of the liquid-attracting element and the liquid-repelling element is made of a cloth material.

6. The thermal device of claim 1, wherein at least one of the liquid-attracting element and the liquid-repelling element is made of a paper material.

7. The thermal device of claim 1, wherein the liquid-attracting element comprises charge-polarized molecules that are capable of hydrogen bonding.

8. The thermal device of claim 1, wherein the liquid-repelling element comprises one or more of an alkane, oil, fat, grease, or polytetrafluoroethylene (PTFE).

9. The thermal device of claim 1, wherein the liquid comprises water.

10. The thermal device of claim 9, wherein the liquid-attracting element is hydrophilic and the liquid-repelling element is hydrophobic.

11. The thermal device of claim 1, wherein the interior space is maintained in a vacuum.

12. The thermal device of claim 1, wherein a thermal resistance of the device changes with ambient temperature change.

13. An object comprising:
a substrate; and
a thermal device integrated into the substrate, the thermal device including a sealed housing that defines an interior space, a liquid-attracting element provided on one side of the interior space, a liquid-repelling element provided on another side of the interior space opposite to the liquid-attracting element, and a liquid provided within the interior space.

14. The object of claim 13, wherein the object is a wearable object.

15. The object of claim 13, wherein the object is a house or building.

16. The object of claim 13, wherein the object is a heat-producing electrical device.

17. The object of claim 13, wherein the object is a thermal storage unit.

18. A method for controlling heat transfer, the method comprising:
providing a liquid-attracting element, liquid-repelling element, and a liquid within a sealed housing; and
orienting the housing so as to control the direction through which heat flows through the housing.

19. The method of claim 18, wherein heat will flow through the housing from the liquid-attracting side of the housing to the liquid-repelling side of the housing.

20. The method of claim 18, wherein the liquid is water, the liquid-attracting element is hydrophilic, and the liquid-repelling element is hydrophobic.
